(19) United States
(12) Patent Application Publication
(10) Pub. No.: US 2024/0369161 A1
(43) Pub. Date: Nov. 7, 2024

(54) FOCUS TUBE OUTLET PROTECTORS

(71) Applicant: Donald Stuart MILLER, Milton Keynes (GB)

(72) Inventor: Donald Stuart MILLER, Milton Keynes (GB)

(21) Appl. No.: 18/262,636

(22) PCT Filed: Jan. 25, 2022
(86) PCT No.: PCT/GB2022/000009

§ 371 Date: Jul. 24, 2023

(30) Foreign Application Priority Data
Jan. 25, 2021 (GB) 2100999.8

(51) Int. Cl. F16L 9/10; B26F 3/00; C23C 16/27; F16L 9/14

(52) U.S. Cl. CPC F16L 9/10; B26F 3/004; C23C 16/27; F16L 9/14

(57) ABSTRACT

A composite chemical vapour deposition diamond (CVDD) focus tube (30, 32, 50) for an abrasive waterjet cutting tool comprises a CVDD tube with a protective ring (55) of superhard material, such as polycrystalline diamond (PCD), CVDD or cubic boron nitride (CBN) at its outlet end. The CVDD tube is encased in a reinforcing material such as a metal or metal alloy, or a plastics material that has set solid in situ. The reinforcing material (38, 51, 81, 91) supports the CVDD tube and in most versions the protective ring, too. The protective ring extends across an outlet face of the composite CVDD focus tube to protect it from abrasive and water reflected back from a workpiece on to the outlet face. The protective ring may be formed as an integral part of the CVDD tube or may comprise a separately formed element mounted to the outlet end of the CVDD tube. The protective ring may be mounted to a former around which the CVDD tube is then formed, or it may be attached by means of the reinforcing material, such as metal deposited by plating.

### FIELD OF APPLICATION

The present invention relates to focus tubes for cutting heads of abrasive waterjet cutting machines.

### BACKGROUND

Abrasive cutting jets for machining are generated by passing ultrahigh pressure water through a restrictor to generate a supersonic waterjet. The waterjet traverses a chamber in a cutting head and enters the bore of a focus tube. On entering a focus tube bore, a waterjet causes a vacuum that induces fluid carrying abrasive particles to flow via the chamber in the cutting head into the bore of the focus tube. In the bore of the focus tube, momentum is transferred from the waterjet to the abrasive particles. A focus tube bore needs a length to diameter ratio of up to 80 for optimum momentum transfer from the waterjet to the abrasive particles.

The momentum transfer process within the bore of a focus tube results in extreme erosive conditions, requiring focus tubes manufactured from ultrahard or superhard materials-superhard materials are those having a hardness of >40 GPa. It also requires focus tube bores to be continuous, without joints that high-velocity abrasive particles could attack. The most wear resistant material is diamond, with a hardness of 70-150 GPa. The only known method of producing high aspect ratio bores in diamond without discontinuities is to grow diamond by chemical vapour deposition (CVD) on to a former, and to etch or machine out the former. CVD diamond has a crystalline structure of interlocking crystals and is extremely brittle. CVD diamond growth rates are about one micron per hour. It is not economic to produce CVD diamond tubes that would be robust enough to withstand the typical forces imposed on tubes whilst they are being handled, during cutting operations and due to inadvertent contact with workpieces.

Several methods of reinforcing CVD diamond focus tubes to withstand internal and external forces are described in granted and patent applications. Prior art reinforced composite focus tubes have suffered from failures that have prevented commercial exploitation. Except for US Patent Application No US2020/0023492, prior art methods of reinforcing CVD diamond tubes have been suited to reinforcing tubes having smooth external surfaces, whereas conventionally grown CVD diamond tubes have a rough, faceted external surface. Even when reinforcement is by a method that conforms to faceted surfaces, axial stress can be generated that places strain on boundaries between crystallites.

The best available focus tubes are made from a monolithic piece of reacted tungsten carbide. These focus tubes have lives of about 80 hours when passing garnet abrasive having a hardness of 13 GPa. It would be highly desirable to extend the life of focus tubes to 1000 hours or so. This would allow a substantial reduction in machine downtime and minimise cut parts going out of tolerance from focus tube wear. Only diamond has the wear resistance to potentially reach 1000 hours when passing garnet abrasive, before a bore becomes oversize.

Cutting ceramics and other very hard materials requires aluminium oxide abrasive with a hardness of 20 GPa or silicon carbide with a hardness of 28 GPa. For example, the life of a tungsten carbide focus tube is a few hours when passing aluminium oxide and minutes when passing silicon carbide. CVD diamond tubes have lives of tens of hours when passing aluminium oxide and silicon carbide abrasive.

The most concentrated erosive conditions to which a focus tube can be subjected occur on the focus tube's outlet face. An abrasive jet is reflected on itself when drilling into a workpiece and impacts almost at right angles on an outlet face of the focus tube. A jet impacts an outlet face for only a small part of a focus tube's operating life, but its erosion capability is extreme. Erosion depths observed on worn-out focus tubes, made from a reacted tungsten carbide, can be greater than wear depths within the bore of the focus tube. Erosion is the deepest about a bore diameter from a centreline of the bore. Wear extends close to the bore but not into the bore, probably because of the exiting abrasive jet's effect on reflected jet flow patterns. Outlet face wear does not affect monolithic focus tubes' functioning, but it can destroy the reinforcing structure around a CVD diamond tube.

CVD diamond focus tubes need their outlets to be made of superhard material. The material needs to extend sufficiently radially away from the bore to protect the non-diamond parts of a composite focus tube from erosion from reflected abrasive and water. A weakness of CVD diamond is its crystalline structure of interlocking diamond crystallites. A reflected abrasive jet impacting a CVD diamond outlet surface causes stress waves to propagate away from impact sites. On reaching a reinforcing surface, little of a stress wave propagates into the reinforcing material because of a large mis-match in the speed of sound in diamond and in the reinforcing material. Tension waves propagate away from the interface between diamond and reinforcing material. Interfaces are between CVD diamond faceted crystal surfaces and reinforcing material, so complex wave interactions occur. CVD diamond is known to fail when it is subject to tension waves at interfaces that are not sufficiently supported by reinforcing material. Intimate contact is thus required between the faceted CVDD surface of an outlet ring and reinforcing material to avoid failure.

Except for US Patent Application No US2020/0023492, the prior art is silent about how reinforced CVD diamond focus tubes might be prevented from being damaged by reflected abrasive and water. It is envisaged in US Patent Application No US2020/0023492 that outlet protectors would be replaced as they became worn. However, replacing worn outlet protectors is not always practical.

When CVD diamond tubes are reinforced to withstand internal and external loads, they are referred to hereinafter as composite CVDD focus tubes. An outlet protector may be grown as an integral part of a CVDD focus tube, or it may form an integral part of the structure of the tube reinforcement. When the protector is part of the reinforcing structure, it is advantageously made of polycrystalline diamond (PCD) which, like CVD diamond, consists of diamond crystals, but with the crystals fused together. PCD is more resistant to crack propagation than CVD diamond. Cubic boron nitride (CBN) is classed as a superhard material, and can also be used for CVDD focus tube protectors.

A ring of protector material at the outlet of a composite focus tube is taken to mean any shape of superhard material that protects the outlet against reflected abrasive and water.

It can also be advantageous for some cutting head designs for abrasive to flow over a front face of the focus tube, before entering an inlet of the focus tube. A ring of superhard material may thus be desirable at the inlet to the focus tube to avoid erosion of adjacent reinforcing material.

Abrasive is taken herein to mean particulate material used for eroding workpieces, such as particles of garnet, aluminium oxide, tungsten carbide and/or silicon carbide.

### SUMMARY OF THE INVENTION

A main objective of the present invention is to provide composite CVDD focus tubes that can withstand erosive wear on their outlet faces for a sufficient time for its focus tube to become worn out by erosive wear in the bore of the tube before the tube fails from other causes. A further objective is to provide composite CVDD focus tubes that can withstand inadvertent light impacts with workpieces. When a cutting head design requires abrasive particles to flow over a front face of a composite CVDD focus tube, it is another objective of the present invention to provide such protection for reinforcing material of said front face.

Composite CVDD focus tubes embodying the present invention have an outlet end of diamond or very hard material of sufficient extent as to protect the non-diamond parts of a tube from excessive erosion by abrasive jets deflecting from workpieces on to an outlet face of the focus tube. A sufficient extent of a protector surface at a focus tube outlet may be achieved during the process of growing a diamond tube on a former in a CVDD reactor. It may also be achieved by adding a ring made of a superhard material such as diamond, either bonded to a CVDD tube or to a structure surrounding a CVDD tube.

When multiple CVDD focus tubes are grown on a former consisting of a wire, rod or tube with machined features or constructs along said wire, rod, or tube, the etching process to remove the former causes the individual tubes to separate. Features and constructs can have an outer periphery on to which the CVD diamond does not deposit. The etching process then first etches away the construct and separates the tubes, before etching out the former from within the tube bore. Alternatively, if diamond has deposited on a feature or construct, individual tubes can be separated by attacking this diamond with a laser or other cutting means, allowing etchant to reach the former and to separate the CVDD focus tubes. Part or all of the process of removing a former from a CVDD tube bore can be carried out by machining. Using a hollow former reduces the time taken to etch away that former.

The forces generated by abrasive, water and air flowing through a bore of a focus tube are mainly axial. These forces can be small relative to the axial loading capability of a CVDD tube having wall thicknesses that are sufficient to conduct heat away from concentrated areas of abrasive impact and/or are sufficient to support the operations needed to reinforce a CVDD tube. Any material used to reinforce a CVDD tube must support the discharge end of the focus tube to prevent tube failure during inadvertent light contact with a workpiece. Alternatively, a protector ring has to be adapted to shield the end of a CVDD tube from impacting a workpiece.

An inherent problem with abrasive waterjet cutting of brittle materials is crack propagation, caused by high water pressures entering an existing crack. Water droplets that impact surfaces at high speed cause water hammer pressures. These pressures can be much higher than the driving pressures behind the waterjet. Any surface damage to a CVDD focus tube increases the potential for droplet impacts to cause cracks to propagate along diamond crystal boundaries. Droplet impacts occur on a focus tube outlet between starting the water flow and the abrasive reaching a cutting head and cutting commencing. CVDD diamond crystals are not bonded together but are interlocked. PCD consists of diamond grains that are intergrown. Intergrown grains greatly hinder crack propagation, making PCD more tolerant of impact by water droplets and abrasive particles than CVDD. The disadvantage of PCD protector rings, however, is that they either entail a join in the focus tube bore close to an outlet of the bore or a join around the outlet of the CVDD focus tube itself. Both of these joins would be at risk of attack by abrasive particles. Problems with these joints can be mitigated, however.

A preferred method of reinforcing a CVDD focus tube is by deposition of nickel, although other metals or alloys can be deposited, as can flowable materials that subsequently set by chemical reaction. Electrolytic and electroless deposition of metal and alloys takes place on to diamond surfaces that have been prepared for deposition.

Preparation of diamond surfaces can involve the use of conductive metallic inks and paints, for example based on copper. A cage or reinforcing structure can be positioned over a CVDD tube and integrated with that tube by nickel deposition or deposition of other materials. Electroless metal deposition allows bonding in confined spaces between a reinforcing structure and a CVDD tube. A PCD ring can be brazed or otherwise joined to a cage or reinforcing structure before the cage is joined to a CVDD tube. By controlling the conditions in a plating bath, the deposition process can be arranged to control the stresses imposed on a CVDD tube by the deposition process.

As the thickness of deposited CVDD diamond increases, there is a tendency for ever larger faceted crystallites to form. If the outside of a diamond tube were smooth, the ideal would be for reinforcements to apply a high radial compressive stress to a diamond cylinder. However, radial forces acting on the faces of crystallites may in turn cause axial forces. These forces could result in crack propagation along crystallite boundaries. When a radially compressive force is applied, such as by a cylinder of shape memory alloy, a malleable layer is needed between a CVDD tube and the material applying the radially compressive force. Features in the internal wall of a cylinder applying such a compressive force can be provided to allow for displacement of the material of the malleable layer.

Diamond has a thermal expansion coefficient typically less than ten percent of the coefficient for metals (except for the special case of the alloy invar). In operation, the surface temperature of a monolithic tungsten carbide focus tube increases from the inlet to the outlet of the tube by 60° C. or so. However, temperatures within such a focus tube reach over 1900° C., which can melt the abrasive; this is known because melted abrasive grains are found when abrasive is collected in water after passing through a focus tube which has not been involved in cutting. These temperatures are believed to occur at wear fronts that propagate from the inlet to the outlet of the bore of the focus tube. Depending on the current stage of the life of a focus tube, several of these wear fronts can be progressing along the bore of the tube.

Abrasive particles, water and air travel along the bore of a focus tube at velocities that exceed twice the speed of sound therein. It is considered that very steep temperature gradients exist, local to wear fronts, that require a minimum diamond wall thickness for sufficient heat conduction to prevent excessive thermally-induced stresses between the diamond and the reinforcing/supporting material. A wall thickness equivalent to the bore diameter is probably required to conduct heat away from a wear front well enough to avoid thermal stress that would cause cracks from faults in the CVDD to propagate. Numerous such faults at crystal grain boundaries are inevitably created during the CVDD growth process.

Typically, water mass flow rates are eight to ten times the abrasive mass flow rate. The thermal capacity of water under static conditions would be adequate to minimise focus tube temperatures. Under dynamic conditions within focus tubes, though, it is considered that heat transfer to water has little effect on local violent events such as at wear fronts. However, heat transfer to water droplets along a focus tube bore is responsible for maintaining the bulk temperature of the focus tube below 100° C.

Conditions in reactors used to grow CVDD result in varying deposition rates radially and longitudinally on formers. When a CVDD tube is grown with a coating thickness equivalent to several bore diameters, the centreline of a bore and the centreline of an outer diameter of the tube may differ by as much as the bore diameter. A bore being offset relative to the outside diameter of the tube presents challenges in reinforcing a CVDD tube. Methods are available to precision machine parts of composite CVDD focus tubes so that when mounted to a cutting head, its bore centreline is coincident with a centreline of the waterjet. If reinforcement has been by casting a material that sets by chemical reaction, the centreline of the outside diameter of a CVDD focus tube at its inlet end can be arranged to be coincident with the centreline of the bore of its focus tube. With a sufficient length of coincident surface diameter for location, the remainder of a composite CVDD tube can where necessary be shaped for a gradual transition to a reinforcing/protecting ring having an outside diameter that is not coincident with the centreline of the tube.

According to the present invention, there is provided a composite chemical vapour deposition diamond (CVDD) focus tube for a cutting head of an abrasive waterjet cutting machine,
said composite CVDD focus tube comprising:
   an elongate CVDD tube having a through bore extending longitudinally between an inlet end of the CVDD tube and an outlet end of the CVDD tube, said elongate CVDD tube being provided adjacent its outlet end with a protective element comprising a superhard material, said protective element extending radially outwardly across an outlet face of the composite CVDD focus tube;
   and further comprising a body of reinforcing material extending around the CVDD tube and contacting at least a part of its external surface so as to support the CVDD tube.

Preferably, the protective element comprises an integral part of the CVDD tube.

Alternatively, the protective element is mounted to the outlet end of the CVDD tube.

The protective element may comprise a preformed body of superhard material comprising part of a former about which the elongate CVDD tube was then grown.

Portions of the preformed body may then be treated to prevent diamond deposition on the treated portions during the diamond growth processes.

Preferably, the protective element comprises a protective ring or annulus of superhard material.

The protective ring may comprise a central aperture aligned with an outlet end of the bore of the CVDD tube.

Said central aperture may then have the same diameter as or a slightly greater diameter than an outlet end of the bore of the CVDD tube.

The protective ring may alternatively comprise a central aperture configured to receive an outlet end of the CVDD tube therein.

The protective element may extend transversely to a longitudinal axis of the bore of the CVDD tube, optionally extending perpendicularly thereto.

The protective element may extend to cover an entire outlet face of the composite CVDD focus tube

The superhard material of the protective element preferably comprises diamond.

Advantageously, the superhard material of the protective element comprises polycrystalline diamond having intergrown crystals.

Alternatively or additionally, the superhard material of the protective element comprises chemical vapour deposition diamond.

Preferably, the body of reinforcing material contacts and supports both the external surface of the CVDD tube and the protective element.

Preferably, the body of reinforcing material comprises a metal or metal alloy.

Advantageously, the exterior surface of the CVDD tube is then activated to receive a coating of metal or alloys by plating.

Optionally, the protective element may be attached to the CVDD tube by plated metal.

Alternatively, the reinforcing material comprises a fluid material that sets by chemical reaction.

A cage or other construct may be positioned around the CVDD tube and joined by plating to a part or all of a faceted growth surface of the CVDD tube.

Preferably, an external surface of the reinforcing material is machined with reference to a centreline of the bore of the CVDD tube to allow the composite CVDD focus tube to be mounted to a cutting head with the centreline of the focus tube bore aligned with a centreline of a water jet orifice or nozzle.

In an alternative embodiment, a protective element comprising a superhard material is mounted adjacent the inlet end of the CVDD tube, extending across an inlet face of the composite CVDD focus tube.

### LIST OF FIGURES

Embodiments of the present invention will now be more particularly described by way of example and with reference to the Figures of the accompanying drawings, in which:

FIG. 1 is a longitudinal section of a first cutting head of known form with a monolithic focus tube;

FIG. 2 is a longitudinal section of a second cutting head embodying the present invention, with a composite focus tube;

FIGS. 3a and 3b are each longitudinal sections of composite focus tubes embodying the present invention, as shown in FIG. 2;

FIG. 4 is a longitudinal section of a further composite focus tube embodying the present invention, with a superhard outlet protector ring;

FIG. 4a is a scrap sectional view of an alternative tip for the composite focus tube of FIG. 4;

FIG. 5 is a longitudinal section of a further composite CVDD focus tube embodying the present invention, with an offset bore;

FIGS. 6a to 6d show, as a sequence of longitudinal sections, a manufacturing sequence for composite CVDD focus tubes embodying the present invention;

FIG. 7 is a longitudinal section of another composite focus tube embodying the present invention; and

FIG. 8 is a longitudinal section of another composite focus tube embodying the present invention.

### DETAILED DESCRIPTION

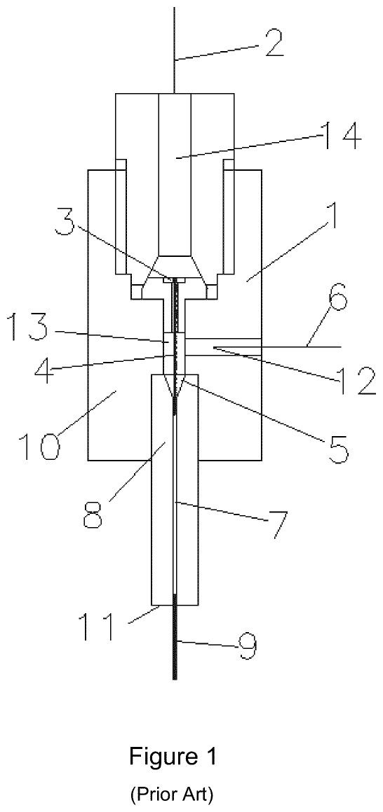

Referring now to the Figures of the accompanying drawings and to FIG. 1 in particular, this shows a first abrasive waterjet cutting head 1 of known form, with a monolithic focus tube 8 formed from a single piece of superhard material. Water from an ultrahigh pressure source 2 enters the cutting head 1 through a collimation tube 14 and passes through a waterjet orifice or nozzle 3 to generate a high-speed waterjet 4. The waterjet traverses a chamber 13 in a body 10 of the cutting head 1, passes through a contracting inlet 5 and enters a bore 7 of the focus tube 8. In entering the bore 7 of the focus tube 8, the high-speed waterjet 4 causes a vacuum that draws fluid, carrying abrasive particles, from a source 6 to flow through a passage 12 into the chamber 13 and on into the focus tube bore 7. In the focus tube bore 7, momentum is exchanged between the high-velocity water jet 4 and abrasive particles to generate an abrasive jet 9 at an outlet 11 of the focus tube 8. The cutting head 1 is manipulated by a robotic motion system (not shown) directing the abrasive jet 9 to cut, drill and mill workpieces (not shown).

When an abrasive jet 9 first impacts a workpiece, the abrasive jet 9 is caused to turn back on itself and impacts the outlet face 11 of the focus tube 8. In turning back, an abrasive jet 9 produces a larger diameter hole in a workpiece than the diameter of the abrasive jet 9 itself. Depending on the size of a gap between a workpiece and the focus tube outlet 11, the reflected jet impact is concentrated on the outlet face 11, some distance from the actual outlet of the bore 7. If the cutting head 1 is moving over a workpiece surface and the abrasive jet 9 is reflecting on to the outlet face 11 of a focus tube 8, wear on the outlet face 11 is concentrated on that part of the outlet face 11 opposite the direction of motion of the cutting head 1.

Ultrahard/superhard materials are brittle. Conventional focus tubes 8 have a diameter of eight to twenty times the diameter of the bore 7 to avoid failure from an accidental impact on a workpiece. The outlet face 11 is sufficiently extensive to intercept abrasive jet 9 deflected back from a workpiece, so that it does not miss the outlet face 11 and possibly impact other parts of the equipment. A deflected abrasive jet 9 will impact on the outlet face 11 away from the bore 7, and so actual cutting performance is not affected by the erosion of the outlet face 11 away from the bore 7.

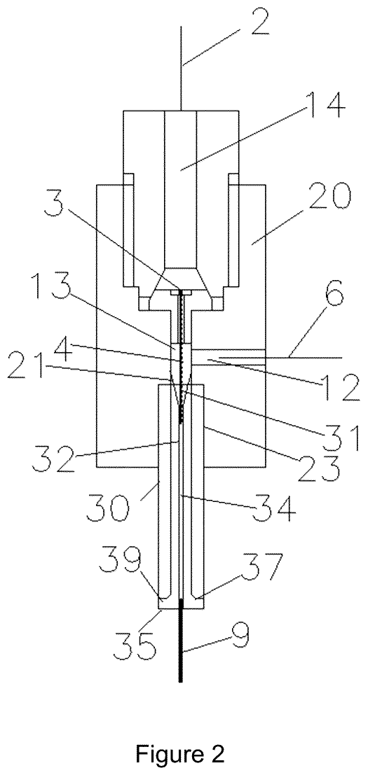

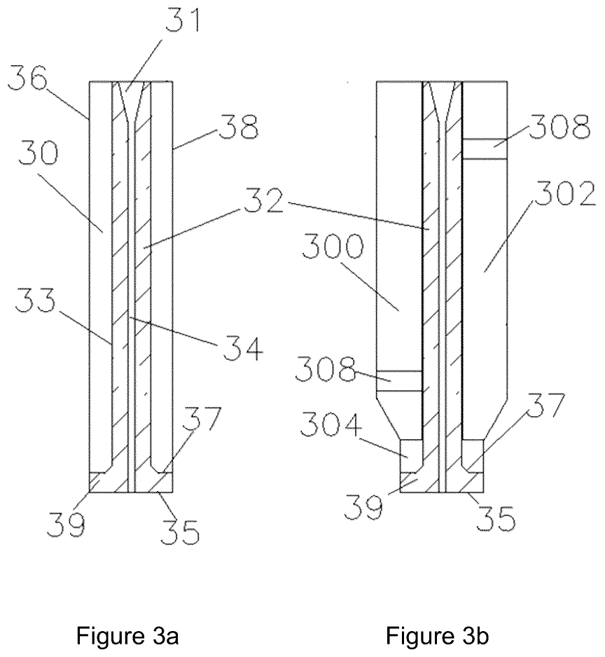

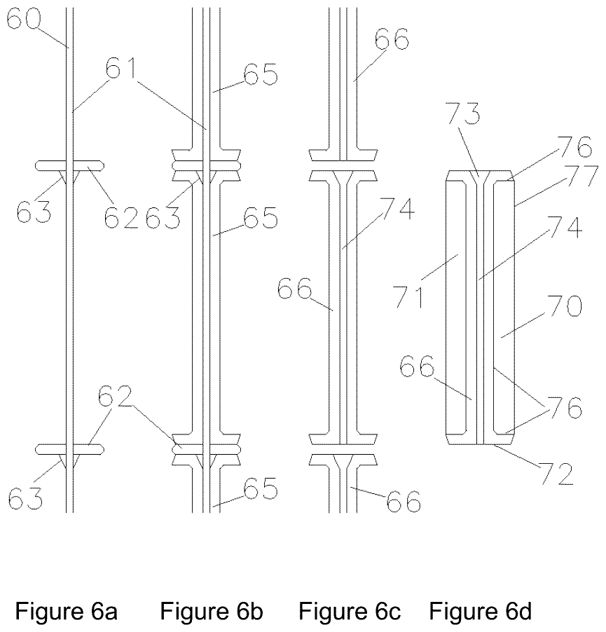

Referring now to FIG. 2, this shows a second cutting head 20 similar to the first cutting head 1 of FIG. 1, but with a composite CVDD focus tube 30 (as shown in more detail in FIG. 3a). The cutting head 20 in this particular example has an inlet guide 21 that allows a reduction in an inlet diameter of an inlet contraction 31 of the composite focus tube 30. A CVDD tube 32 has been grown on a former (shown below) in a CVDD reactor. The former has then been etched or machined away. The inlet contraction 31 can be produced by a profile of the former on which the CVDD tube 32 was grown, or it can be machined into a bore 34 of the CVDD focus tube 32 (see FIG. 3a and FIGS. 6a to 6d for an example of a manufacturing process).

An outlet end 39 of the CVDD focus tube 32 has a larger outer diameter than a remainder of the focus tube 32. Reinforcing material 38 has been plated, grown or deposited on to an external surface of the CVDD tube 32. Particular attention is given to ensure that the faceted external surface of the CVDD focus tube 38 is fully supported by the reinforcing material 38, especially in a terminal region 37 of the focus tube 38, to minimise the adverse effects of compression stress waves propagating away from impacts of water droplets and abrasive particles on an outlet face 35 of the CVDD focus tube 32, these compression stress waves being reflected as tension waves. A preferred deposition process for the reinforcement material 38 is nickel plating. Another preferred material is a polymeric material, advantageously one that is reinforced with ceramic or metal particles. An outside diameter 36 of the composite CVDD tube 30 has been machined to match a bore 23 constructed to receive it within the second cutting head 20.

FIG. 3b shows an alternative composite CVDD focus tube 300 with a CVDD focus tube 32 as in FIG. 3a, coated with deposited metal, alloy or polymeric material 304 adjacent its terminal region 37, which supports and reinforces the terminal region 37 and outlet end of the CVDD focus tube 32. A holder 302 surrounds the CVDD focus tube 32, which is held within the holder 302 in a similar manner to the focus tubes disclosed in US Patent Application No US2020/0023492. Several passageways 308 allow for injection into a cylindrical volume 303 between the holder 302 and the CVDD focus tube 32 of a fluid material, which sets by chemical reaction, so as to encase the CVDD focus tube 32.

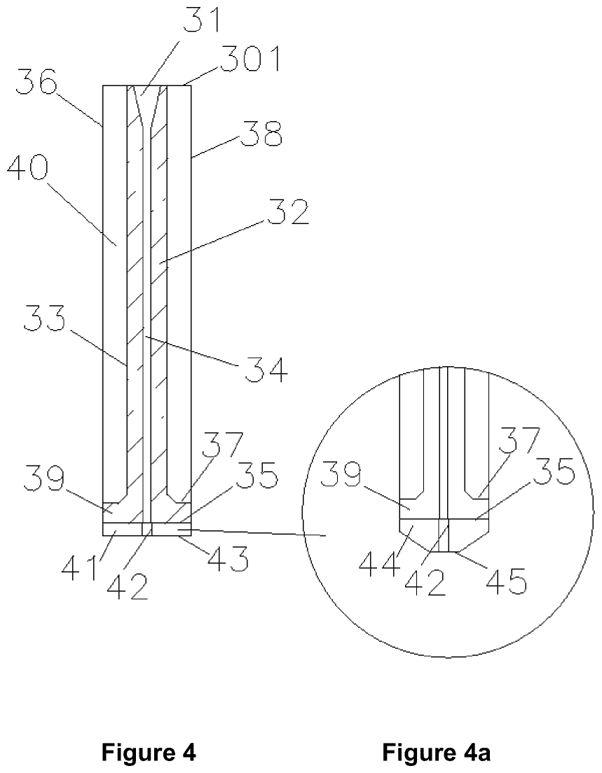

Referring now to FIG. 4, this shows a further composite CVDD focus tube 40, which is similar to the composite CVDD focus tube 30 of FIG. 3a, except that part of the former on which the CVDD focus tube 32 was grown consisted of a superhard (PCD, cubic CBN or CVDD) ring 41, which forms an outlet face 43 of the composite CVDD focus tube 40. There is thus an interface between the superhard ring 41 and the outlet face 35 of the CVDD focus tube 32. The material of the ring 41 is chosen better to resist crack propagation caused by particle and droplet impact on its outlet face 43 than the interlocked diamond crystals of the CVDD focus tube 32 and its respective outlet end 35. To avoid disrupting the abrasive jet 9 as the bore 34 of the CVDD focus tube 32 grows, a central aperture 42 of the superhard ring 41 may be marginally larger than the bore 34, as long as the superhard ring 41 is more resistant to erosion than the material defining the bore 34 in the CVDD focus tube 32.

FIG. 4a shows a more complex superhard ring 44 having a profiled outlet face 45 instead of the flat outlet face 43, perpendicular to a longitudinal axis of the bore 34 that is shown in FIG. 4.

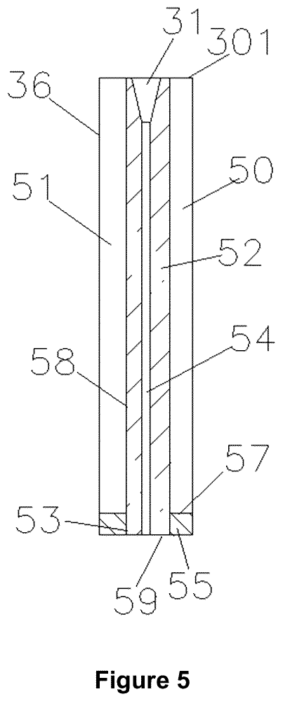

Referring now to FIG. 5, this shows a further composite CVDD focus tube 50 that has a CVDD or PCD protective ring 55 fitted over an outlet end of its CVDD tube 52 before deposition of the reinforcing material 51 on to an outer surface 58 of the CVDD focus tube 52 and a reverse surface 57 of the protective ring 55. A bore 54 through the CVDD focus tube 32 is in this case is not central within the focus tube 52. This is a common feature of the diamond growth process within CVDD reactors, such that diamond thickness varies radially and axially. The protective ring 55 may have an offset central aperture 53, so that when it is fitted over the CVDD focus tube 52, the centreline of an outside diameter of thee protective ring 55 is coincident with that of the bore 54 of the CVDD focus tube 52.

Water and abrasive reflected from workpieces on to an outlet face 59 of the composite CVDD focus tube 50 as a whole may impact a gap at the central aperture 53 between the protective ring 55 and faceted surfaces of diamond crystals forming an adjacent portion of the CVDD focus tube 32. Flow paths between these crystals and the central aperture 53 in the protective ring 55 prevent a build-up of water pressure. The risk of removing diamond grains on an outer surface of the CVDD focus tube 52 adjacent the outlet face 59 increases with an increase in abrasive particle size and mass. Depending on the diameter of the CVDD focus tube 52, the entire composite CVDD focus tube 50 of FIG. 5 may only be suited for micromachining with abrasive waterjet machining systems that use fine abrasive powder.

FIGS. 6a to 6d show the stages of producing a composite CVDD focus tube 70 (shown complete in FIG. 6d). A former 60 on which a series of CVDD focus tubes 65 is grown comprises a wire, rod or tube 61 of any of a variety of materials that would be well-known to one skilled in the art of growing CVDD items in a reactor. Added formers 62 and 63, shaped to define an increased outlet diameter and an inlet contraction 73 respectively, are crimped or otherwise attached to the wire, rod, or tube 61 at distances appropriate for CVDD focus tubes 66 of a desired length. Alternatively, similar shapes may be machined into a thicker, monolithic wire, rod or tube. The added former 62 has an outer edge treated so that CVD diamond does not grow on this edge. CVDD is deposited on the former 60 in a reactor to generate the series of CVDD focus tubes 65, as in FIG. 6b. The former 60 is then removed by etching resulting in the series of CVDD focus tubes 65 separating into individual CVDD tubes 66 as shown in FIG. 6c. The treated outer edge of the added former 62 allows the added former 62 to be more easily etched away to separate the individual CVDD focus tubes 66, as shown in FIG. 6c.

If the added former 62 was not treated to prevent CVD diamond deposition on its outer edge, a laser or other machining means can be used to remove deposited diamond and allow acid etchant to reach all the parts of the former 60, 61, 62 and 63. The properties of formers 60 can in some cases be transformed during the diamond growth process, with tungsten formers being converted to tungsten carbide, for example.

The complete composite CVDD focus tube 70 has a thick coating of nickel-phosphorous or other reinforcing material deposited or grown on its outer surface 76. It is then machined to produce an outer surface 77 for the composite CVDD focus tube having a diameter 77 suitable for mounting in a cutting head of an abrasive waterjet cutting machine, with a bore 74 of the CVDD focus tube 66 having a centreline coincident with an intended centreline of a waterjet from the cutting machine.

Part of the added former 62 may in alternative processes consist of PCD or CVDD with a facing of a material such as tungsten carbide. If this is the case, the etching process removes the tungsten carbide facing to provide an outlet face 72 for the composite CVDD focus tube 70 comprising PCD or CVDD having different characteristics to the CVDD making up the focus tube 66 itself.

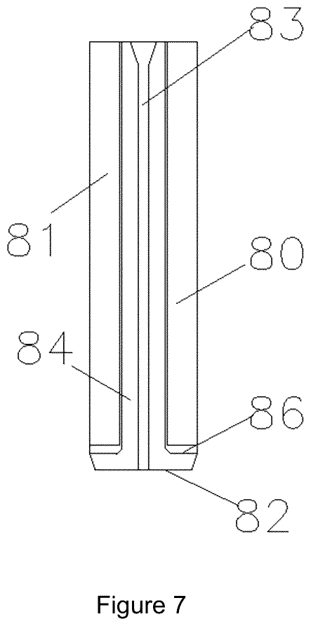

FIG. 7 shows another composite CVDD focus tube 80 similar to the composite CVDD focus tube 30 of FIG. 3a, but with a cage 81 being positioned around its CVDD focus tube 84. The CVVD focus tube 84 has a wall thickness sufficient to conduct heat away from intense wear fronts propagating down its bore 83. A CVDD focus tube 84 with a wall thickness sufficient for such heat transfer is likely to be sufficiently robust to withstand mechanical forces from abrasive and water, particularly when fine abrasive is used for micromachining. This CVDD focus tube 84 only needs support at locations spaced along its length. The cage 81 can have radial, axial or spiral passageways incorporated to allow electroless nickel plating or other deposition processes to deposit material to support the CVDD focus tube 84 at locations along its length. The cage 81 allows deposition of material that provides intimate support to its increased-diameter outlet ring 82 on its reverse face 86.

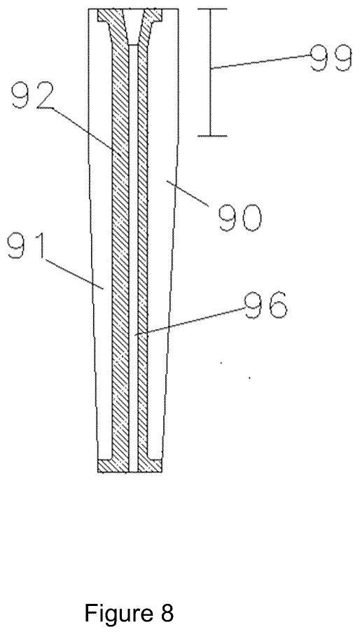

Referring now to FIG. 8, this shows another composite CVDD focus tube 90 with its CVDD focus tube 92 encased in a reinforcing material 91. In a hot filament CVDD reactor, deposition of diamond on formers arranged around a central heating element is lower on surfaces that are shielded from the heating element. A wall thickness of the CVDD focus tube 92 thus varies. For a centreline of a bore 96 of the CVDD focus tube 92 to line up with an intended centreline of a waterjet from a cutting machine fitted with the composite CVDD focus tube 90, a diameter of the reinforcing material 91 over a proximal section 99 of the composite CVDD focus tube 90 is machined or cast to give a required profile relative to the centreline of the bore 96.

The composite CVDD focus tubes described in the present application can be grown in known CVDD reactors by those experienced in the art of growing CVDD articles on formers. This includes knowing how to avoid CVDD growth on selected areas of the formers. Plating and other methods of deposition of materials on to CVDD and other surfaces can be carried out by those experienced in the art of plating, including masking and other practices to prevent plating on selected surfaces and within bores.

Any machining operations necessary to align the centrelines of focus tubes when they are mounted within abrasive waterjet cutting heads, with a centreline of a high-speed waterjet, to within microns, can be carried out by those skilled in the art of precision machining and in the design and manufacture of any jigs and fixtures necessary for such precision machining operations.

1-22. (canceled)

23. A composite chemical vapour deposition diamond (CVDD) focus tube for a cutting head of an abrasive waterjet cutting machine,
said composite CVDD focus tube comprising:
an elongate CVDD tube having a through bore extending longitudinally between an inlet end of the elongate CVDD tube and an outlet end of the elongate CVDD tube,
said elongate CVDD tube being provided adjacent its outlet end with a protective element comprising a superhard material,
said protective element comprising an integral part of the elongate CVDD tube extending radially outwardly across an outlet face of the composite CVDD focus tube; and
the composite CVDD focus tube further comprises a body of reinforcing material extending around the CVDD tube and contacting at least a part of its external surface so as to support the CVDD tube.

24. A composite CVDD focus tube as claimed in claim 23, wherein the protective element comprises a protective ring or annulus of superhard material.

25. A composite CVDD focus tube as claimed in claim 24, wherein the protective ring comprises a central aperture aligned with an outlet end of the bore of the elongate CVDD tube.

26. A composite CVDD focus tube as claimed in claim 25, wherein said central aperture has the same diameter as or a slightly greater diameter than an outlet end of the bore of the elongate CVDD tube.

27. A composite CVDD focus tube as claimed in claim 23, wherein the protective element extends transversely to a longitudinal axis of the bore of the elongate CVDD tube.

28. A composite CVDD focus tube as claimed in claim 27, wherein the protective element extends perpendicularly to a longitudinal axis of the bore of the elongate CVDD tube.

29. A composite CVDD focus tube as claimed in claim 23, wherein the protective element extends to cover an entire outlet face of the composite CVDD focus tube

30. A composite CVDD focus tube as claimed in claim 23 wherein the superhard material of the protective element comprises diamond.

31. A composite CVDD focus tube as claimed in claim 30, wherein the superhard material of the protective element comprises polycrystalline diamond having intergrown crystals.

32. A composite CVDD focus tube as claimed in claim 30, wherein the superhard material of the protective element comprises chemical vapour deposition diamond.

33. A composite CVDD focus tube as claimed in claim 23, wherein the body of reinforcing material contacts and supports both the external surface of the elongate CVDD tube and the protective element.

34. A composite CVDD focus tube as claimed in claim 23, wherein the body of reinforcing material comprises a metal or metal alloy.

35. A composite CVDD focus tube as claimed in claim 34, wherein the exterior surface of the elongate CVDD tube is activated to receive a coating of metal or alloy by plating.

36. A composite CVDD focus tube as claimed in claim 34, wherein the protective element is attached to the elongate CVDD tube by plated metal.

37. A composite CVDD focus tube as claimed in claim 23, wherein the reinforcing material comprises a fluid material that sets by chemical reaction.

38. A composite CVDD focus tube as claimed in claim 23, wherein a cage or other construct is located around the elongate CVDD tube and is joined by plating to a part or all of a faceted growth surface of the elongate CVDD tube.

39. A composite CVDD focus tube as claimed in claim 23, wherein an external surface of the reinforcing material is machined with reference to a centreline of the bore of the elongate CVDD tube to allow the composite CVDD focus tube to be mounted to a cutting head with the centreline of the focus tube bore aligned with a centreline of a water jet orifice or nozzle.

40. A composite CVDD focus tube as claimed in claim 23, wherein a protective element comprising a superhard material is mounted adjacent the inlet end of the elongate CVDD tube, extending across an inlet face of the composite CVDD focus tube.

41. A composite chemical vapour deposition diamond (CVDD) focus tube for a cutting head of an abrasive waterjet cutting machine,
said composite CVDD focus tube comprising:
an elongate CVDD tube having a through bore extending longitudinally between an inlet end of the elongate CVDD tube and an outlet end of the elongate CVDD tube,
said elongate CVDD tube being provided adjacent its outlet end with a protective element comprising a superhard material,
said protective element comprising a preformed body of superhard material extending radially outwardly across an outlet face of the composite CVDD focus tube,
said preformed body comprising part of a former about which the elongate CVDD tube was then grown; and
the composite CVDD focus tube further comprises a body of reinforcing material extending around the CVDD tube and contacting at least a part of its external surface so as to support the CVDD tube.

42. A composite CVDD focus tube as claimed in claim 41, wherein portions of the preformed body are treated to prevent diamond deposition on said treated portions during growth of the elongate CVDD tube.
